(19) United States
(12) Patent Application Publication
(10) Pub. No.: US 2006/0240640 A1
(43) Pub. Date: Oct. 26, 2006

(54) Isostatic pressure assisted wafer bonding method

(76) Inventors: Vitali Nesterenko, La Jolla, CA (US); Mervyn L. Rudee, La Jolla, CA (US); Philip Mages, Thousand Oaks, CA (US); YaBei Gu, La Jolla, CA (US)

Correspondence Address: GREER, BURNS & CRAIN, 300 S WACKER DR, 25TH FLOOR, CHICAGO, IL, 60606, US

(21) Appl. No.: 10/531,553

(22) PCT Filed: Oct. 17, 2003
(86) PCT No.: PCT/US03/33132

§ 371 Date: May 2, 2006

Related U.S. Application Data
(60) Provisional application No. 60/419,477, filed on Oct. 18, 2002.

(51) Int. Cl. H01L 21/30; H01L 21/46

(52) U.S. Cl. 438/455

(57) ABSTRACT

In the invention, wafers are initially weakly bonded. The weak bond is sufficient to impede penetration of an isostatic pressure transmitting media, e.g., a gas or liquid, into any region between the wafers. The weak bond also permits handling. Weak bonds are strengthened, or new bonds formed, by heating and pressing together the weakly bonded wafers by application of isostatic pressure. By the invention, weak interfacial bonds may be strengthened.

### TECHNICAL FIELD

A field of the invention is semiconductors. The invention concerns wafer bonding.

### Background Art

Many fields have an interesting in joining wafers together. The joining together of wafers to form a unified device is interesting, for example, for forming devices that have components from two different material systems, such as silicon based technology and Group III-V based technology. The integration of the two material systems opens a wide range of device possibilities through the synergy of combining desirable aspects of one material system with the different and complementary aspects of another material system.

Similarly, it is of interest to integrate different ones of the example silicon and Group III-V technologies. For example, combined AlGaAs—GaAS—GaN is of interest as it would allow for very wide bandgap materials to be integrated with materials to which the formation of a p-contact is not so difficult. The marriage of multiple silicon wafers is also interesting, for example, to increase the area available for integrated circuit development beyond the size limitations imposed by silicon wafer technology. More generally, wafer bonding to bring together like substrates (homobonding) and unlike substrates (heterobonding) provides the potential for improvement of existing technologies, integration of different technologies, and a new field of endeavor for research that was previously limited by implementation on a single wafer.

In the art, there are both direct and indirect bonding techniques. Direct bonding is the joining wafers without the use of an intervening layer, which has a purpose of providing a strong bond. Indirect bonding involves use of oxides or reactive interlayers. Metallic or oxide interlayers inhibit tailoring of interfaces for any use besides mechanical joining, or perhaps contact formation, in the case of a conductive interlayer. Most low temperature bonding techniques involve the use of some sort of interlayer, most often an oxide formed from the materials.

Direct bonding, sometimes called wafer fusion, provides material with more flexible applicability, but is much more difficult to achieve. Producing a strong direct bond by a repeatable manufacturing process remains an elusive goal in the art. Direct bonding allows the bonded materials to be integrated into the active regions of the device for full utilization of the properties of both materials. Such fusion normally requires high temperature treatments to ensure a covalent bond between the different materials. Therefore, the most difficult applications of wafer bonding are those where two materials having different thermal expansion coefficients are fused together.

Typically, direct bonding is achieved under high temperatures with some form of a rigid mechanical vise constructed of suitable materials for the temperatures and ambients to be used. The controllability of such devices relies heavily on the precise tightening of screws or bolts, or even the placing of a large weight on top of the samples or fixture. Another method for pressing the wafers together relies on the thermal expansion of the sample and parts of the pressure fixture to exert large forces pushing the wafers together during a heating stage. For example, by placing the sample between two pieces of graphite and then placing the resulting group inside of a hole machined from a solid block of quartz, huge pressures will be exerted on the sample upon heating as the graphite and sample attempt to expand against the nearly expansion free quartz. In this method, control of the pressure exerted relies on the ability to shim the sample/graphite combination within the hole in the quartz. Other materials can be used for the expansion-caused pressure fixture, but the selection of quartz and graphite is common due to the materials' cleanliness and the ability of these materials to withstand high temperatures and allow large pressure application.

These methods of applying uniaxial pressure on the samples suffer from difficulty in control of the pressure applied. While the vise or weight methods are more easily reproduced, the attainable pressures are not as great as the hundreds to thousands of MPa attainable using the thermal expansion method. The major disadvantage of the thermal expansion method, however, is the difficulty in controlling the applied pressure since it is nearly impossible to quantify the amount of pressure being exerted at the annealing temperature for a given arrangement of graphite, sample and shims. The most important difficulty associated with both methods is that of applying the pressure evenly over larger and larger areas as the size of the sample or wafer is increased. Especially in the case of the thermal expansion method, even small inhomogeneities, such as the presence of particles between the shims, lead to inhomogeneous pressure application and bonding failure.

One way to avoid the difficulties associated with thermal expansion mismatch is to use lower temperature bonding procedures. This is the advantage that makes the use of reactive interlayers or oxides attractive. In order to avoid bonding at high temperature, while still creating a direct covalent bond between the crystals involved, ultra-high vacuum (UHV) systems have also been employed. Such ultra-clean environments allow for high temperature heat treatments of the wafers to cause the necessary desorption and release of surface passivating species from the samples. The resulting surfaces, though highly reactive due to the unsatisfied bonding requirements of the surface atoms, are not able to react with anything since the UHV chamber is devoid of material for such reaction. The samples can then be cooled to lower temperatures and brought into contact so that the reactive surfaces can instantaneously form covalent bonds. The lower temperature bonding results in lower levels of thermal stress as the samples are cooled to room temperature. A disadvantage of this technique is the requirement of an UHV chamber with extremely low background pressures. Such chambers have low throughput due to the times needed for purging and pumping to the necessary vacuum. In general, the use of such vacuum chambers is prohibited in industrial settings where large material volumes need to be processed. There remains a need for an improved wafer bonding process.

### DISCLOSURE OF THE INVENTION

In the invention, wafers are initially weakly bonded. The weak bond is at least sufficient to impede penetration of an isostatic pressure transmitting media, e.g., a gas or liquid, into any region between the wafers. The weak bond also permits handling. Weak bonds are strengthened, or new bonds formed, by heating and pressing together the weakly bonded wafers by application of isostatic pressure. By the invention, weak interfacial bonds may be strengthened.

### BRIEF DESCRIPTION OF THE DRAWINGS

FIGS. 1A and 1B are graphs of example temperature and pressure ramps for experiments conducted in accordance with the present invention.

### BEST MODE OF CARRYING OUT THE INVENTION

The invention concerns a method for creating a strong bond, and is capable of creating a strong direct bond. Homobonds and heterobonds may be achieved with the invention. In another embodiment of the invention, an indirect bond with an interlayer is formed, but a primary aspect of the invention is the formation of a strong direct bond. In an embodiment of the invention, the surfaces of wafers to be bonded are cleaned to remove particle and chemical contaminants from bonding surfaces of the wafers. Ideally, the result of this procedure is a set of flat, smooth wafers having only the presence of surface passivating species on the crystal surfaces. Most often, these surface passivating species are oxides of the wafer materials. In the case of bonding where the desired bond is a direct bond between the materials themselves, the passivating species is usually atomic hydrogen chemically bonded to the wafer surfaces. Preliminary weak bonds may be formed by a hydrophobic technique or a hydrophilic technique, for example. The bonding surfaces of the wafers are brought together to weakly bond the wafers to each other. This likely produces spontaneous bonding via Van der Waals or Hydrogen bonding mechanisms. However, experiments confirm that the prepared bonding surfaces need only be brought into intimate contact. Whether or not a true bond forms at that point is not clear, though it is likely that the aforementioned Van der Waals or hydrogen bonding mechanisms produce the weak bond. Weak bond and weak bonding, as used herein, therefore encompasses bringing the prepared bonding surfaces into an intimate contact to form a barrier that permits outside isostatic pressure to compress the wafers together at a rate that is substantially faster than fluid penetration into the tiny gap between the wafers. There is not an upper limit or measure on the strength of the weak bond, as weak is used as a relative term herein to mean the bond formed before heat and pressure treatment.

Strengthening of the bonding is achieved via heat treatment of the bonded wafers. The weakly bonded wafers are placed in a pressurization chamber. The chamber is purged. Isostatic pressure is applied to the wafers, e.g., through an inert gas, without any direct mechanical contact being made with the wafers by a rigid mechanical member for the purpose of pressing. The isostatic pressure in the pressurization chamber is the sole mechanism of applying pressure to the wafers while heating the wafers for a period of time to substantially strengthen bonding between the wafers.

Preliminary weak bonding of semiconductor wafers provides a necessary sealing to prevent or substantially impede entrance of the isostatic pressure transmitted medium between the wafers. Pressure exerted accordingly acts substantially on the large exposed surfaces of the wafers, exerting substantial forces to press the wafers together. No sealed container is required, and multiple pairs of wafers may be treated to increase bond strength in a single pressurization chamber. Preliminary weak bonding helps avoid the need for sealing wafers undergoing bonding into vacuum tight container. If the weak bonding is not conducted, i.e., adequately intimate contact between adequately prepared wafer surfaces is not effected, a strong bond will not be obtained by isostatic pressure and heat treatment.

Application of isostatic pressure simultaneously with heat treatment at suitable pressures, temperatures and times improves the weak bond and produces strongly bonded wafers. Conditions may be optimized for different materials, including for direct bonding of wafers having a large thermal mismatch. Using isostatic pressure results in a uniform application of pressure. A suitable gas medium is an inert gas medium, e.g., Argon for example, and is preferably applied in a Hot Isostatic Press (for example QIH-3). Isostatic pressure media with higher viscosity further reduces the possibility of significant penetration between wafers being heat and isostatic pressure treated. Similarly, the use of an inert liquid is possible, with the distinction between gases and liquids disappearing at high pressures and temperatures. Certain low strength solids, at sufficiently high pressures, may also substantially exhibit isostasy, in which case they could be used to practice the invention.

As a result of the invention, pressure and temperature may be independently controlled during the isostatic pressure assisted bonding process, offering the opportunity for optimizations not possible in conventional processes where there is a strong dependency between pressure and temperature. Accordingly, with the invention the residual level of stresses may be controlled for optimal conditions.

The independent control of pressure and temperature provided by the invention also provides the ability for strain tailoring. It is possible to tailor strains in the bonded wafers by changing level of pressures, as long as level of pressure is adequate to ensure bonding. Pressure and temperatures are applied independently in the invention and each of them introduce corresponding strains, which may be of different sign due to a different nature. There is a wide range of potential pressures to produce equally good bonding. For example, experiments have shown equally good bonds at pressures in a range from 0.5 kbar to 2 kbar, and the permissible range will vary depending on the wafers being bonded. Changing a level of pressure induces strains significantly at the same level of thermal strains in an appropriate temperature cycle.

Successful bondings using the invention have been achieved at relatively low pressures and temperatures. Pressure ramps having a maximum of 2 Kbars, and temperature ramps having a maximum of 700° C. have produced strongly bonded samples. The factors to consider for selection of an appropriate temperature and pressure ramps include, for example, temperature stability of the materials involved, temperature and pressure dependence of dopant or impurity diffusion within the wafers, or structural behavior of any layers used between wafers when indirect bonding is used. These factors may be used to help determine optimizations for particular embodiments of wafer bonding processes, as the conditions on pressure, temperature and time for achieving a desirable level of strong bonding of wafers are not believed to logically follow a particular physical law. Different cycles for different materials should be tested to reach a particular optimization. Experiments by the inventors do, however, confirm that a wide range of temperatures and pressures for different homobonds and heterobonds should succeed, so long as an interfacial configuration that prevents substantial pressure between the wafers is achieved prior to application of isostatic pressure and temperature. The materials themselves and the type of bonding needed determine the temperatures and ambients used for this heat treatment. For example, direct covalent bond between wafers have been achieved with heat treatment typically in excess of 500° C. using an inert gas or H₂ ambient as an isostatic medium.

The isostatic pressure transmitted media used in the chamber is preferably inert but can be varied according to the desired application and necessary purity. A gaseous medium is similar to a liquid medium since the two are mechanically similar in their behavior, especially in cases of high pressure where there is no meaningful distinction between the two phases. For the purposes of the invention, their similarity is due to the fact that they both create the state in which pressures exhibit isostasy. Samples are then heated and the chamber is pressurized according to the desired conditions. Pressure is applied solely via an isostatic medium, e.g., pressurization of the gas inside the chamber. Temperature levels and ramps can be controlled independently of pressure levels and ramps, making the process fit for tailoring to specific requirements of the materials system involved. Temperature levels ranging from normal to 2000° C. are available as well as pressure levels from vacuum to 2 kbar in typical hot isostatic presses. In conducted experiments, successful strong bonds were achieved with temperatures in the range of 520° C.-830° C., typical time periods of about 2 hours, and typical pressures ranging from vacuum −2 kbar.

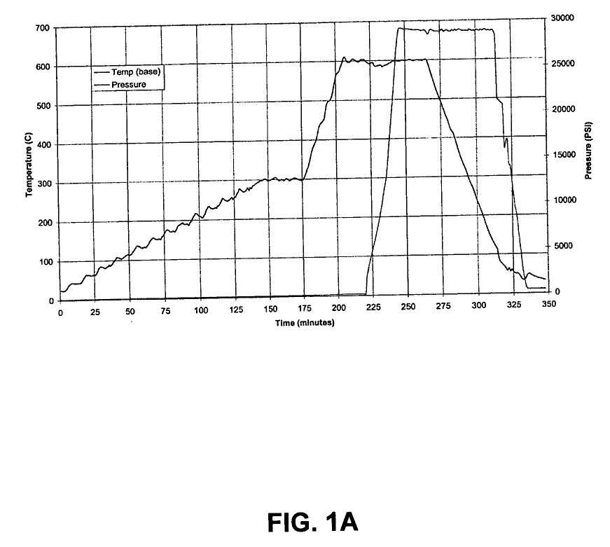

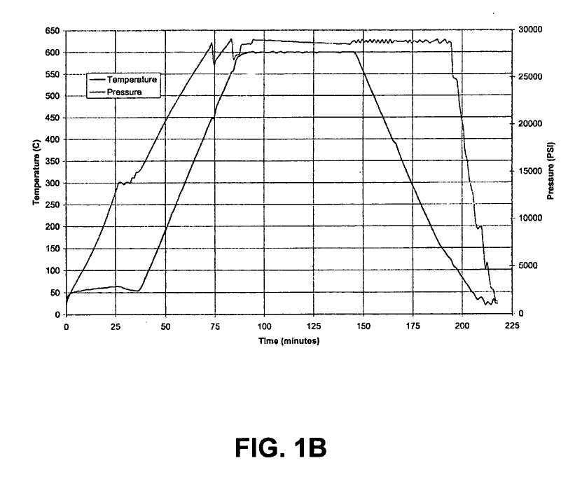

Example temperature and pressure ramps from experiments are shown in FIGS. 1A and 1B. In the experiments, small pieces of wafers (10 by 10 mm) were used and experiments were also conducted with two inch Si—InP wafers (the two inch wafers will not bond by any explained mechanism, but clean wafers were brought into intimate contact). FIG. 1A shows a pressure and temperature cycle used to successfully bond Si—InP wafers, with temperature applied first, before pressure application. FIG. 1B shows a qualitatively different pressure and temperature cycle used to successfully bond Si—InP wafers with pressure applied first before heating. Despite a pressure application to relatively cold wafers, they were very well preserved. In both cases, we used cooling under pressure to inhibit wafer fracturing due to the thermal mismatch on the stage of cooling. Force applied to wafers corresponding to a maximal pressure of 200 MPa was about 40 ton. We do not know any results where such enormous force is applied to wafers mechanically using some type of rigid vise or unidirectional pressing.

Methods of the invention can work even where the weak bond is not defect free. We also conducted experiments using a weak prebonding method with intentional contamination to bond two inch Si—Si wafers. Specifically, we used hydrophobic prebonding with intentional contamination with water of part of interface to ensure remaining large bubbles on the interface. After standard heat treatment of Si—Si wafers in low pressure (about 200 Torr hydrogen atmosphere at 600 C) large bubbles result. Application of subsequent hot gasostatic pressing demonstrated that isostatic pressure can close existing bubbles without fracturing the wafers. A cycle similar to that shown in FIG. 1B was used to bond wafers nonideally hydrophobic prebonded with additional heat treatment in low pressure hydrogen atmosphere at 600 C. Small bubbles were practically closed and the size of large bubbles was significantly reduced without wafer fracture. Additionally, thickness of the unbonded outside layer was also reduced. Thus, the method of the invention can tolerate, at least in some cases, defects, and even heal defects, like large bubbles, in bonded wafers.

The application of pressure evenly over the large area of sample and the ability to maintain pressure during the stage of cooling are unique capabilities provided by the invention that significantly improve the strength of the bond between the two (or more) wafers involved. Such treatment allows for materials with different thermal expansion coefficients to be joined despite stresses arising from the thermal mismatch. Furthermore, the nature of the pressure application allows for uniform pressure to be placed on bonded samples with complex geometry or on multiple weakly bonded wafer pairs simultaneously without their macroscopic plastic deformation.

Hot isostatic pressing is traditionally used for large macroscale operations like densification of powders and castings, diffusion bonding of structural materials like bronze and steel, ceramic-metal bonding. The use of the isostatic mediated pressure application to preliminary weakly bonded wafers of semiconducting materials for enhancement of a strong bonding with desirable optoelectronic properties without encapsulation is unique. The use of hot isostatic pressing of wafers as the basis for semiconductor devices has not been previously demonstrated, to our knowledge. It has been uninvestigated perhaps because the relatively low level of pressures (about 2 kbars or less) and temperatures (below −700° C.) applied during a reasonable time do not make it immediately apparent that bonding will be successful, while ensuring useful optoelectronic properties. Also, without the inhibition of pressure penetration between the wafers, application of isostatic pressure would not have the desired effect of pressing the wafers together. It is not intuitively apparent that the gas or liquid will be prevented from penetrating the interface without the presence of a relatively strong bond.

Low levels of plastic deformation and wafer bending may result from application of the invention. These effects are minimized in the invention since uniform isostatic pressure application to weakly bonded wafers at an arbitrary size, orientation or geometry minimizes the plastic deformation of bonded wafers. After application of the invention, experimental samples have been treated as a single wafer, e.g., cleaved, annealed and processed using various etching and semiconductor device formation techniques. In InP/Si heterobonded samples, localized stress lines were observed while most of the surfaces were free from stress lines. This was observed with low quality epitaxial wafers used in experiments, and is likely to be further limited with higher quality samples. One possible conclusion from a largely defect free surface in low quality samples is that the method of the invention provides a bonding process that is less sensitive to particle contamination and less sensitive to growth defects. The appearance of defects at the bonded interfaces may be prevented by the application of isostatic pressure through the invention since many such defects involve an increase in volume, which would be less energetically favorable under high isostatic pressure. Additional advantages can be connected with decrease of temperature and time required to achieve a strong bonding due to pressure application.

The ability to monitor the pressure application independently during the heating and pressing of weakly bonded wafers is also important. Rigid mechanical contact wafer pressing techniques, e.g., anvil type devices, typically rely either on differential thermal expansion or on the tightening of a vise prior to heating in order to produce the desired pressures. As a result, the pressures exerted are linked to the temperature increase both of the sample and fixture. By the invention, the pressure can be set independently of the sample temperature and can be kept constant not only during the heating run, but also during the stage of cooling also. The isostatic pressing provides a reproducible method of applying pressure independently of temperature that is not attainable using mechanical tightening of rigid vises or shimming of differential thermal expansion devices.

Experiments have confirmed Si/Si homobonding, InP/InP homobonding, InP/Si heterobonding and epitaxial InGaAs-on-InP/Si heterobonding. The experiments used preliminary hydrophobically bonded wafers. Such wafers are prepared so as to have hydrogen terminated surfaces before Van der Waal bonding. The bond formed at room temperature between these wafers is very weak, but is sufficient to allow handling of the wafers for loading into a hot isostatic pressure chamber, and to prevent penetration of a pressure transmitting media (for example argon gas) into the space between wafers. This allows using direct application of isostatic pressure to wafers without wafer encapsulation. In one set of experiments, the specific pressure assisted process consisted of a temperature ramp of 2° C./min to 300° C. for a dwell time of 30 minutes before beginning a 10° C./min ramp to 650° C. where the temperature was maintained for 65 minutes. The samples were cooled at a rate of about 10° C./min maintaining the constant gasostatic pressure. The pressure was controlled such that no significant pressure was applied until the samples had dwelt at 650° C. for 10 minutes. At this time, the pressure was then ramped to a final pressure of 200 MPa over the next 45 minutes. The high pressure was maintained for the remaining 10 minutes of 650° C. heating and for the whole cooling process.

Upon removal from the chamber, all samples were found to be very strongly bonded together, even those samples where thermal stresses are known to cause bonding failure without the application of pressure. A sample having the epitaxially grown InGaAs-on-InP structure bonded to Si was successfully processed into a simple photodetector. Unlike samples having this same structure but different bonding processes, these samples showed no etching or delamination anomalies during the device processing steps. Furthermore, the detectors exhibited photo-induced current without any applied voltage. Such behavior was not observed in experimental detectors previously fabricated by researchers at the University of California at San Diego using standard rigid anvil based bonding techniques.

Other embodiments of the invention involve the use of an unsealed container to help preserve a clean atmosphere during handling, but permit the isostatic pressure to be applied. A non- sealed container creates a local atmosphere that minimizes the wafer damage that can be induced chemically. Wafers may be placed into a container, and wafer pairs or groups being bonded may be supported, for example, by rods made from inert material, e.g., ceramics or stainless steel depending on temperature. Small holes in the container allow pressurization of the isostatic pressure transmitted media inside but limit convection and help to preserve a local clean atmosphere helping to prevent wafer deterioration. A container with weakly bonded wafers loaded, for example, in a clean room can be placed into the chamber of hot isostatic press or another device for application of isostatic pressure. Use of an unsealed container allows use of inexpensive graphite furnaces, for example, a device used in our experiments.

While specific embodiments of the present invention have been shown and described, it should be understood that other modifications, substitutions and alternatives are apparent to one of ordinary skill in the art. Such modifications, substitutions and alternatives can be made without departing from the spirit and scope of the invention, which should be determined from the appended claims.

Various features of the invention are set forth in the appended claims.

1. A method for wafer bonding, the method comprising steps of:
providing wafers to be bonded;
cleaning the wafers to remove particle and chemical contaminants from bonding surfaces of the wafers;
bringing the bonding surfaces of the wafers together to weakly bond the wafers to each other;
placing the wafers in a pressurization chamber;
solely through isostatic pressure, applying bonding pressure to the wafers;
heating the wafers during said step of applying bonding pressure; and
controlling and maintaining said steps of heating and applying bonding pressure for a period of time to substantially strengthen bonding between the wafers.

2. The method of claim 1, further comprising steps of:
cooling the wafers; and
removing the wafers from the pressurization chamber.

3. The method of claim 2, wherein said step of cooling is conducted while said step of controlling and maintaining continues said step of applying bonding pressure, followed by a step of depressurization.

4. The method of claim 1, wherein said step of controlling and maintaining comprises:
creating a temperature ramp and a pressure ramp to substantially strengthen bonding between the wafers.

5. The method of claim 4, wherein said step of controlling and maintaining creates the temperature ramp as a function that is independent from the pressure ramp.

6. The method of claim 1, wherein said step of heating commences prior to said step of applying pressure.

7. The method of claim 1, wherein said step of heating commences with or after said step of applying pressure.

8. The method of claim 1, wherein said step of cleaning creates hydrogen terminated surfaces at the bonding surfaces.

9. The method of claim 1, wherein said step of bringing creates one of a Van der Waals and Hydrogen bond.

10. The method of claim 9, wherein said step of bringing brings the bonding surfaces into direct contact with each other without an intervening layer.

11. The method of claim 9, wherein the wafers are of the same material.

12. The method of claim 9, wherein the wafers are of different materials.

13. The method of claim 9, wherein said step of bringing brings together the bonding surfaces with an interlayer between the surfaces.

14. The method of claim 1, further comprising, immediately prior to said step of applying and said step of heating, purging the pressurization chamber.

15. The method of claim 1, wherein said step of applying bonding pressure comprises using Argon as a isostatic pressure medium.

16. The method according to claim 15, wherein the pressurization chamber comprises a hot isostatic press.

17. The method of claim 1, wherein said steps of providing, cleaning and bringing are repeated to form a plurality of weakly bonded pairs of wafers and said steps of applying, heating, and controlling and maintaining are carried out with the plurality of weakly bonded pairs of wafers simultaneously in the pressurization chamber.

18. The method of claim 1, further comprising, prior to said step of placing, loading said wafers in an unsealed container, and wherein said step of placing is carried out by placing said unsealed container in said pressurization chamber.

19. A method for wafer bonding, the method comprising steps of:
bonding together wafers by bringing the wafers together after the wafers have been prepared;
heating and pressing together wafers bonded in said step of bonding by application of isostatic pressure via a pressure ramp and temperature ramp that strengthens the bond between the wafers bonded in said step of bonding.

20. The method of claim 19, further comprising a step of controlling said heating and pressing to induce strain in at least one of said wafers.
